(19) United States
(12) Patent Application Publication
(10) Pub. No.: US 2022/0284978 A1
(43) Pub. Date: Sep. 8, 2022

(54) MEMORY CONTROLLER AND METHOD OF OPERATING THE SAME

(71) Applicant: SK hynix Inc., Gyeonggi-do (KR)

(72) Inventor: Dae Sung KIM, Gyeonggi-do (KR)

(21) Appl. No.: 17/404,558

(22) Filed: Aug. 17, 2021

(30) Foreign Application Priority Data
Mar. 3, 2021 (KR) 10-2021-0028428

(51) Int. Cl. G11C 29/42; G11C 29/44; H03M 13/11; H03K 19/21

(52) U.S. Cl. CPC G11C 29/42; G11C 29/4401; H03M 13/1177; H03M 13/1105; H03K 19/21

(57) ABSTRACT

The present technology relates to an electronic device. More specifically, the present technology relates to a memory controller and a method of operating the same. According to an embodiment, a memory controller includes an error corrector configured to receive read data from a memory device and output a first message obtained by performing error correction decoding on the read data based on a parity check matrix, a randomizer configured to generate a second message by inverting the first message, and an operation controller configured to output the second message, wherein the parity check matrix is a matrix in which a number of elements, each of which is one (1) among elements included in each row, is an even number or a matrix in which an exclusive OR on elements included in each row is zero (0).

### CROSS-REFERENCE TO RELATED APPLICATION

The present application claims priority under 35 U.S.C. § 119(a) to Korean patent application number 10-2021-0028428 filed on Mar. 3, 2021, the entire disclosure of which is incorporated by reference herein.

### BACKGROUND

### Field of Invention

The present disclosure relates to an electronic device, and more particularly, to a memory controller and a method of operating the same.

### Description of Related Art

A storage device is a device that stores data under control of a host device. The storage device may include a memory device storing data and a memory controller controlling the memory device. The memory device may be classified into a volatile memory device and a nonvolatile memory device.

The volatile memory device may store data only while receiving power from a power source. When the power supply is cut off, the data stored in the volatile memory device may be lost. The volatile memory device may include a static random access memory (SRAM), a dynamic random access memory (DRAM), and the like.

The nonvolatile memory device may be a device in which the data is not lost even though power of the power source is cut off. The nonvolatile memory device may include a read only memory (ROM), a programmable ROM (PROM), an electrically programmable ROM (EPROM), an electrically erasable and programmable ROM (EEPROM), a flash memory, and the like.

### SUMMARY

An embodiment of the present disclosure provides a memory controller with improved safety of data to be stored during a program operation and improved reliability of a read operation, and a method of operating the same.

According to an embodiment of the present disclosure, a memory controller may include an error corrector configured to receive read data from a memory device and output a first message obtained by performing error correction decoding on the read data based on a parity check matrix, a randomizer configured to generate a second message by inverting the first message, and an operation controller configured to output the second message, wherein the parity check matrix may be a matrix in which a number of elements, each of which is one (1) among elements included in each row, is an even number or a matrix in which an exclusive OR on elements included in each row is zero (0).

According to an embodiment of the present disclosure, a method of operating a memory controller may include generating an inverted codeword according to a preset one of a first policy and a second policy based on write data to be stored in a memory device and a generator matrix, in response to a write request of a host, providing the inverted codeword to the memory device, receiving the inverted codeword from the memory device in response to a read request of the host, performing error correction decoding on the inverted codeword based on a parity check matrix to generate a first message, inverting the first message to generate a second message, and providing the second message to the host, wherein the parity check matrix may be a matrix in which a number of elements, each of which is one (1) among elements included in each row, is an even number or a matrix in which an exclusive OR on elements included in each row is zero (0).

According to an embodiment of the present disclosure, an operating method of a controller may include error-correction-decoding on a codeword, which is read out from a memory device, based on a parity check matrix to generate a message and bitwise-inverting the message to provide a host with the bitwise-inverted message, wherein the codeword is data that is error-correction-encoded based on a generator matrix and then bitwise-inverted when stored into the memory device, wherein the parity check matrix includes one or more rows each having even number of ones (1s), and wherein the generator matrix and the parity check matrix have a relationship as follows: GHT=0, where ‘G’ represents the generator matrix and ‘HT’ represents a transpose matrix of the parity check matrix.

According to an embodiment of the present disclosure, an operating method of a controller may include error-correction-decoding on a codeword, which is read out from a memory device, based on a parity check matrix to generate a message and bitwise-inverting the message to provide a host with the bitwise-inverted message, wherein the codeword is data that is bitwise-inverted and then error-correction-encoded based on a generator matrix when stored into the memory device, wherein the parity check matrix includes one or more rows each having even number of ones (1s), and wherein the generator matrix and the parity check matrix have a relationship as follows: GHT=0, where ‘G’ represents the generator matrix and ‘HT’ represents a transpose matrix of the parity check matrix.

According to an embodiment of the present disclosure, an operating method of a controller may include error-correction-decoding on a codeword, which is read out from a memory device, based on a parity check matrix to generate a message and bitwise-inverting the message to provide a host with the bitwise-inverted message, wherein the codeword is data that is error-correction-encoded based on a generator matrix and then bitwise-inverted when stored into the memory device, wherein the parity check matrix includes one or more rows, each having elements, on which exclusive OR results in zero (0), and wherein the generator matrix and the parity check matrix have a relationship as follows: GHT=0, where ‘G’ represents the generator matrix and ‘HT’ represents a transpose matrix of the parity check matrix.

According to an embodiment of the present disclosure, an operating method of a controller may include error-correction-decoding on a codeword, which is read out from a memory device, based on a parity check matrix to generate a message and bitwise-inverting the message to provide a host with the bitwise-inverted message, wherein the codeword is data that is bitwise-inverted and then error-correction-encoded based on a generator matrix when stored into the memory device, wherein the parity check matrix includes one or more rows, each having elements, on which exclusive OR results in zero (0), and wherein the generator matrix and the parity check matrix have a relationship as follows: GHT=0, where ‘G’ represents the generator matrix and ‘HT’ represents a transpose matrix of the parity check matrix.

According to the present technology, a memory controller with improved safety of data to be stored during a program operation and improved reliability of a read operation, and a method of operating the same are provided.

### BRIEF DESCRIPTION OF THE DRAWINGS

FIG. 1 is a diagram illustrating a storage system according to an embodiment of the present disclosure.

FIG. 2 is a diagram illustrating a memory device according to an embodiment of the present disclosure.

FIG. 3 is a diagram illustrating a memory block according to an embodiment of the present disclosure.

FIG. 4 is a diagram illustrating a codeword stored in a memory device according to an embodiment of the present disclosure.

FIG. 5 is a diagram illustrating an error corrector and a randomizer according to an embodiment of the present disclosure.

FIG. 6 is a diagram illustrating an example of a parity check matrix according to an embodiment of the present disclosure.

FIG. 7 is a diagram illustrating a parity check matrix shown in FIG. 6 as a Tanner graph according to an embodiment of the present disclosure.

FIG. 8 is a diagram illustrating a syndrome vector calculated using the parity check matrix shown in FIG. 6 according to an embodiment of the present disclosure.

FIG. 9 is a diagram illustrating another example of a parity check matrix according to an embodiment of the present disclosure.

FIG. 10 is a diagram illustrating the parity check matrix shown in FIG. 9 as a Tanner graph according to an embodiment of the present disclosure.

FIG. 11 is a diagram illustrating a syndrome vector calculated using the parity check matrix shown in FIG. 9 according to an embodiment of the present disclosure.

FIG. 12 is a diagram illustrating a symbol configuration process according to an embodiment of the present disclosure.

FIG. 13 is a diagram illustrating a process of generating an inverted codeword according to a first policy in accordance with an embodiment of the present disclosure.

FIG. 14 is a diagram illustrating a process of generating an inverted codeword according to a second policy in accordance with an embodiment of the present disclosure.

FIG. 15 is a diagram illustrating a process of generating a message restored from read data according to an embodiment of the present disclosure.

FIG. 16 is a flowchart illustrating a method of operating a memory controller according to an embodiment of the present disclosure.

FIG. 17 is a flowchart illustrating a method of generating an inverted codeword according to a first policy according to an embodiment of the present disclosure.

FIG. 18 is a flowchart illustrating a method of generating an inverted codeword according to a second policy according to an embodiment of the present disclosure.

FIG. 19 is a diagram illustrating the memory controller of FIG. 1 according to an embodiment of the present disclosure.

FIG. 20 is a block diagram illustrating a memory card system to which a storage device according to an embodiment of the present disclosure is applied.

FIG. 21 is a block diagram illustrating a solid state drive (SSD) system to which a storage device according to an embodiment of the present disclosure is applied.

FIG. 22 is a block diagram illustrating a user system to which a storage device according to an embodiment of the present disclosure is applied.

### DETAILED DESCRIPTION

Specific structural or functional descriptions of embodiments according to the concepts which are disclosed in the present specification or application are illustrated only to describe the embodiments according to the concepts of the present disclosure. The embodiments according to the concepts of the present disclosure may be carried out in various forms and should not be construed as being limited to the embodiments described in the present specification.

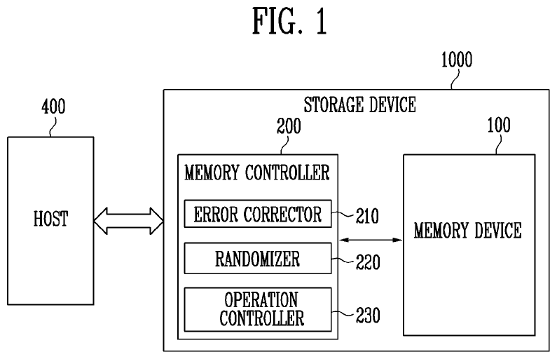

FIG. 1 is a diagram illustrating a storage system according to an embodiment of the present disclosure.

Referring to FIG. 1, the storage system may be implemented as a personal computer (PC), a data center, a corporate data storage system, a data processing system including a direct attached storage (DAS), a data processing system including a storage area network (SAN), and a data processing system including a network attached storage (NAS), or the like.

The storage system may include a storage device 1000 and a host 400.

The storage device 1000 may be a device that stores data according to a request of the host 400 such as a cellular phone, a smartphone, an MP3 player, a laptop computer, a desktop computer, a game player, a TV, a tablet PC, or an in-vehicle infotainment system.

The storage device 1000 may be manufactured as one of various types of storage devices according to a host interface that is a communication method with the host 400. For example, the storage device 1000 may be configured as any of various types of storage devices such as an SSD, a multimedia card in a form of an MMC, an eMMC, an RS-MMC and a micro-MMC, a secure digital card in a form of an SD, a mini-SD and a micro-SD, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, and a memory stick.

The storage device 1000 may be manufactured as any of various types of packages. For example, the storage device 1000 may be manufactured as any of various types of package types, such as a package on package (POP), a system in package (SIP), a system on chip (SOC), a multi-chip package (MCP), a chip on board (COB), a wafer-level fabricated package (WFP), and a wafer-level stack package (WSP).

In an embodiment, the number of storage devices 1000 may be one, as shown in FIG. 1, but is not limited thereto, and the number of storage devices 1000 may be two or more. A plurality of storage devices 1000 may operate in redundant array of independent disks or redundant array of inexpensive disks (RAID) system operating in one storage device logically.

The storage device 1000 may include a memory device 100 and a memory controller 200.

The memory device 100 may operate in response to control of the memory controller 200. Specifically, the memory device 100 may receive a command and an address from the memory controller 200 and access a memory cell selected by the address among memory cells (not shown). The memory device 100 may perform an operation instructed by the command on the memory cell selected by the address.

The command may be, for example, a program command, a read command, or an erase command, and the operation instructed by the command may be, for example, a program operation (or a write operation), a read operation, or an erase operation.

The program operation may be an operation in which the memory device 100 stores data provided from the host 400 in response to control of the memory controller 200.

For example, the memory device 100 may receive the program command, an address, and the data, and program the data in a memory cell selected by the address.

Data provided from the host 400 may be defined as a message.

Data to be provided to the memory device 100 may be defined as a codeword. The codeword may include the message and a parity. The codeword may be generated through error correction encoding of the message.

Data to be programmed to the selected memory cell may be defined as write data. The write data may include data provided from the host 400 and meta data of the data.

The read operation may be an operation in which the memory device 100 reads read data stored in the memory device 100 in response to the control of the memory controller 200.

For example, the memory device 100 may receive the read command and an address, and read data from a region selected by the address in the memory cell array (not shown). The data to be read from the selected region among the data stored in the memory device 100 may be defined as the read data.

The erase operation may be an operation in which the memory device 100 erases the data stored in a memory device in response to the control of the memory controller 200.

For example, the memory device 100 may receive the erase command and an address, and erase data stored in a region selected by the address.

The memory device 100 may be implemented as a volatile memory device or a nonvolatile memory device.

For example, the volatile memory devices may include a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), and the like.

For example, the nonvolatile memory device may include a resistive random access memory (RRAM), a phase-change random access memory (PRAM), a magnetoresistive random access memory (MRAM), a ferroelectric random access memory, a spin transfer torque random access memory, flash memory, and the like. For example, the flash memory may include a NAND flash memory, a vertical NAND flash memory, a NOR flash memory, and the like.

In the present specification, for convenience of description, the memory device 100 is a NAND flash memory.

The memory device 100 may store the write data, or read the stored read data and provide the read data to the memory controller 200, under the control of the memory controller 200.

The memory device 100 may include at least one plane.

The one plane may include a memory cell array (not shown) including memory cells storing the write data.

The memory cell array may include a plurality of memory blocks (not shown). The memory block may be a unit for performing an erase operation of erasing data.

The memory block may include a plurality of pages (not shown). The page may be a unit for performing the program operation of storing the write data or the read operation of reading the stored read data.

The memory cell may be a single level cell (SLC) that stores one bit of data, a multi-level cell (MLC) that stores two bits of data, a triple-level cell (TLC) that stores three bits of data, and a quadruple level cell (QLC) that stores four bits of data. However, the present disclosure is not limited thereto, and the memory cell may store five or more bits of data.

In an embodiment, the memory device 100 may perform an operation instructed by a command in a plane interleaving method. The plane interleaving method may be a method in which operations on each of two or more planes are at least partially overlapped.

The memory controller 200 may control an overall operation of the storage device 1000. The memory controller 200 may include all circuits, systems, software, firmware and devices necessary for its operations and functions.

When power is applied to the storage device 1000, the memory controller 200 may execute instructions, e.g., firmware. When the memory device 100 is a flash memory device, the firmware may include a host interface layer, a flash translation layer, and a flash interface layer. Here, the power may be, for example, power supplied from the outside.

The host interface layer may control an operation between the host 400 and the memory controller 200.

The flash translation layer may convert a logical address provided from the host 400 into a physical address.

The flash interface layer may control communication between the memory controller 200 and the memory device 100.

The memory controller 200 may control the memory device 100 to perform an operation corresponding to a request provided from the host 400. Specifically, the memory controller 200 may control the memory device 100 to perform each of the program operation, the read operation, and the erase operation in response to a write request, a read request, and an erase request of the host 400.

During the program operation, the memory controller 200 may provide the program command, the physical addresses, and the write data to the memory device 100.

In an embodiment, during the program operation, the memory controller 200 may provide the program command and the physical address to the memory device 100.

During the read operation, the memory controller 200 may provide the read command and the physical address to the memory device 100.

During the erase operation, the memory controller 200 may provide the erase command and the physical address to the memory device 100.

The memory controller 200 may generate the command, the addresses, and data autonomously regardless of the request provided from the host 400. The memory controller 200 may transmit the autonomously generated command, address, and data to the memory device 100.

For example, the memory controller 200 may generate a command, an address, and data for performing a background operation. In addition, the memory controller 200 may provide the command, the address, and the data to the memory device 100. The command for performing the background operation may be, for example, the program command or the read command.

The background operation may be at least one of wear leveling, read reclaim, or garbage collection.

The wear leveling may mean, for example, static wear leveling, dynamic wear leveling, and the like. The static wear leveling may mean an operation of storing the number of times memory blocks are erased and moving cold data in which an erase operation or a write operation hardly occurs to a memory block having the largest number of times memory blocks are erased. The dynamic wear leveling may mean an operation of storing the number of times memory blocks are erased and programming data in a memory block having the least number of erase times.

The read reclaim may mean an operation of moving data stored in a memory block to another memory block before an uncorrectable error occurs in data stored in a memory block.

The garbage collection may mean an operation of copying valid data included in a bad block among memory blocks to a free block and erasing invalid data included in the bad block. Here, copying the valid data included in the bad block to the free block may mean moving the valid data included in the bad block to the free block.

The memory controller 200 may control two or more memory devices 100. In this case, the memory controller 200 may control the memory devices 100 according to an interleaving method to improve operation performance.

The interleaving method may be a method of controlling operations of two or more memory devices 100 to overlap.

In an embodiment, the memory controller 200 may generate an inverted codeword by performing error correction encoding and a bit inversion operation on write data. The bit inversion operation may be an operation of inverting a bit included in data. The bit inversion operation may be various according to an embodiment. In addition, complexity of the bit inversion operation may vary according to a randomization method. In an embodiment, the bit inversion operation may be an operation of inverting all bits included in data. Inverting the bit may be defined as a bit flip.

In an embodiment, the memory controller 200 may generate the inverted codeword according to a preset one of a first policy and a second policy.

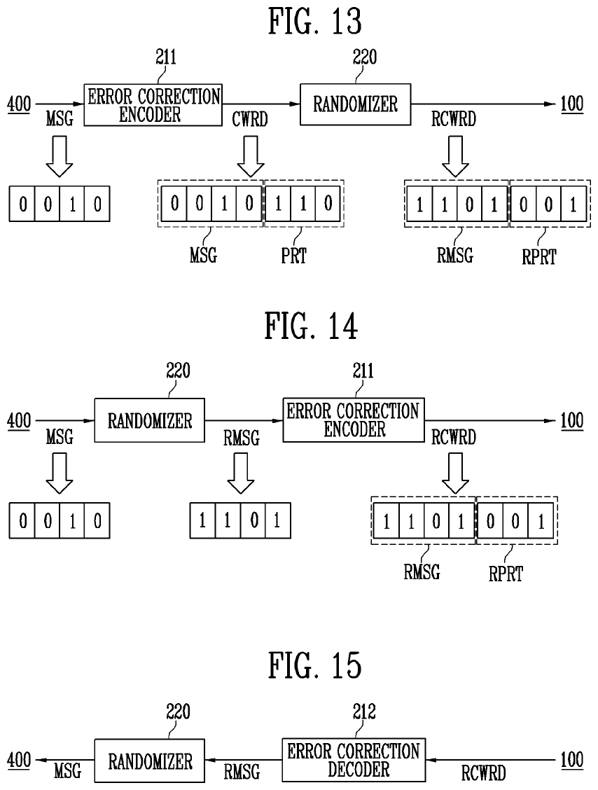

For example, the memory controller 200 may generate the inverted codeword by performing the error correction encoding on the write data provided from the host 400 and inverting a codeword generated according to the error correction encoding of the write data. That is, the first policy may be defined as a policy that performs the bit inversion operation after encoding the write data. This is described with reference to FIG. 13.

For another example, the memory controller 200 may generate the inverted codeword by generating inverted write data obtained by inverting the write data provided from the host 400 and performing error correction encoding on the inverted write data. That is, the second policy may be defined as a policy of inverting the write data and then performing the encoding error correction. This is described with reference to FIG. 14. In a case of the inverted codeword generated according to the second policy, there may be an issue in which all bits included in the message are inverted, but only some bits included in a parity may be inverted.

In an embodiment, the memory controller 200 may restore a message to be provided to the host 400 by performing error correction decoding and a bit inversion operation on read data.

For example, when the read data is generated according to the second policy, the memory controller 200 may perform the bit inversion operation after performing the error correction decoding on the read data when restoring the message.

As another example, when the read data is generated according to the first policy, the memory controller 200 may perform the error correction decoding after performing the bit inversion operation on the read data when restoring the message. In this case, since the bit inversion operation is preceded in order to perform the error correction decoding, read performance of the storage device 1000 may be reduced whenever the error correction decoding is repeated.

Therefore, when considering problems of the first policy and the second policy described above, a method capable of improving the read performance while improving reliability of the error correction operation when one of the first policy and the second policy is used, is required.

In an embodiment, the memory controller 200 may include an error corrector 210, a randomizer 220, and an operation controller 230.

The error corrector 210 may perform the error correction encoding of the write data to be stored in the memory device 100 using a generator matrix of k rows and n columns and generate the codeword, where n is a natural number, and k may be a natural number less than n.

In an embodiment, when the message is configured of k bits, a vector corresponding to the codeword may be calculated by multiplying a vector corresponding to a k-bit message and the generator matrix of k rows and n columns.

In an embodiment, the generator matrix of k rows and n columns may be generated based on a parity check matrix of (n−k) rows and n columns. A transpose matrix in which the parity check matrix of (n−k) rows and n columns is transposed and the generator matrix of k rows and n columns have a relationship as [Equation 1] below.

GH^{T}=0 [Equation 1]

G is the generator matrix, and H is the parity check matrix.

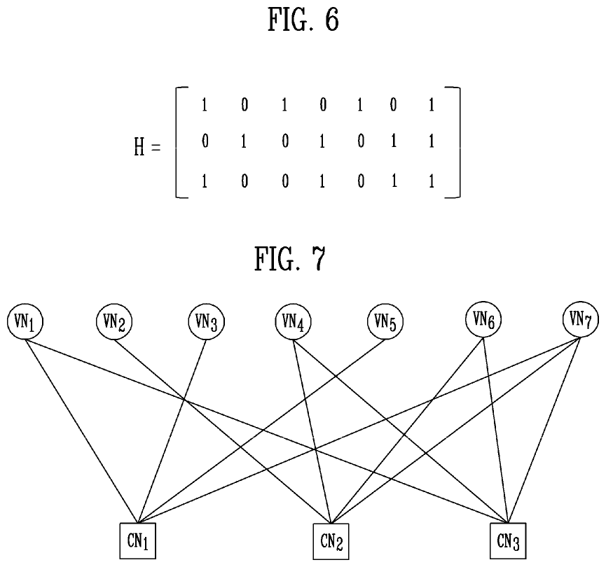

The error corrector 210 may perform the error correction decoding of the read data received from the memory device 100 using the parity check matrix of (n−k) rows and n columns and generate decoded data. A detailed description of the parity check matrix of (n−k) rows and n columns is described later with reference to FIGS. 6 to 12.

The randomizer 220 may invert input data. In an embodiment, the randomizer 220 may invert all bits included in the input data.

The operation controller 230 may generate a command instructing to perform an operation corresponding to a request of the host 400. The command instructing to perform the operation includes, for example, a program command, a read command, an erase command, and the like.

The operation controller 230 may obtain a physical address corresponding to a logical address provided from the host 400.

The operation controller 230 may include, for example, the flash translation layer described above.

In an embodiment, the operation controller 230 may control the error corrector 210 and the randomizer 220 to generate the inverted codeword according to the first policy or the second policy during the write operation. The operation controller 230 may provide the inverted codeword and the program command instructing to store the inverted codeword to the memory device 100.

For example, the operation controller 230 may control the error corrector 210 and the randomizer 220 to invert the codeword generated according to the error correction encoding of the write data after performing the error correction encoding on the write data. As another example, the operation controller 230 may control the error corrector 210 and the randomizer 220 to perform the error correction encoding on the inverted write data after inverting the write data.

In an embodiment, the operation controller 230 may control the error corrector 210 and the randomizer 220 to invert a first message generated according to the error correction decoding of the read data after performing the error correction decoding on the read data during the read operation. At this time, the first message may be data restored through the error correction decoding of the read data. A message obtained by inverting the first message may be referred to as a second message.

The operation controller 230 may provide the second message to the host 400.

Although not shown, the storage device 1000 may further include a buffer memory that stores data only while receiving power from a power supply.

For example, the buffer memory may be a volatile memory device. For example, the buffer memory may be implemented as any of a DRAM, an SRAM, a double data rate synchronous dynamic random access memory (DDR SDRAM), a low power double data rate4 (LPDDR4) SDRAM, a graphics double data rate (GDDR) SDRAM, a low power DDR (LPDDR), and a Rambus dynamic random access memory (RDRAM).

The host 400 may communicate with the storage device 1000 through an interface (not shown).

The interface may be implemented with a serial advanced technology attachment (SATA) interface, a SATA express (SATAe) interface, a serial attached small computer system interface (SAS) interface, a peripheral component interconnect express (PCIe) interface, a nonvolatile memory express (NVMe) interface, an advanced host controller interface (AHCI), or a multimedia card interface. However, the interface is not limited thereto.

The host 400 may communicate with the storage device 1000 to store the data in the storage device 1000 or obtain the data stored in the storage device 1000.

In an embodiment, the host 400 may provide the write request to the storage device 1000 for requesting to store the data in the storage device 1000. In addition, the host 400 may provide the write request, the data, and the logical address for identifying the data to the storage device 1000.

The storage device 1000 may store the write data including the meta data and the data provided by the host 400 in the memory device 100 in response to the write request provided from the host 400, and provide a response that the storage is completed to the host 400.

In an embodiment, the host 400 may provide the read request to the storage device 1000 for requesting to provide the data stored in the storage device 1000 to the host 400. In addition, the host 400 may provide a read request and a read address to the storage device 1000.

The storage device 1000 may read the read data corresponding to the read address provided by the host 400 from the memory device 100 in response to the read request provided from the host 400, and provide the read data to the host 400 as a response to the read request.

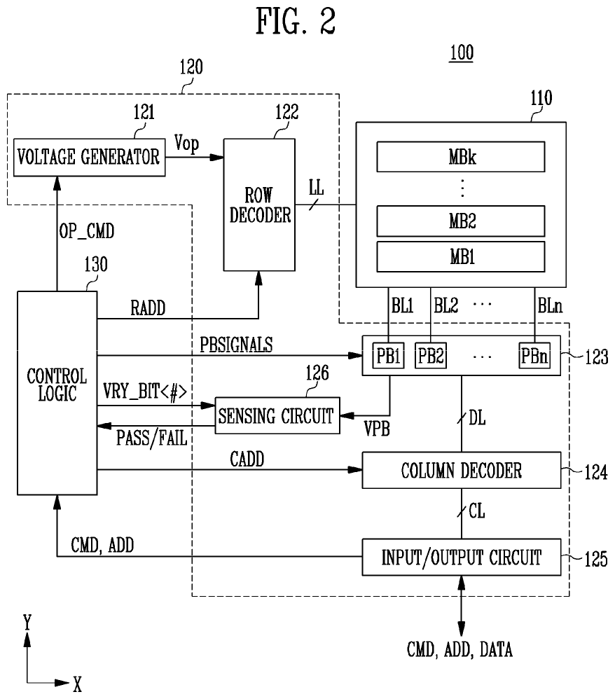

FIG. 2 is a diagram illustrating a nonvolatile memory device according to an embodiment of the present disclosure.

Referring to FIG. 2, the memory device 100 may include the memory cell array 110, a peripheral circuit 120, and a control logic 130.

The memory cell array 110 may include a plurality of memory blocks MB1 to MBk, where k is a positive integer. Here, the number of the plurality of memory blocks MB1 to MBk is only an example for describing embodiments of the present disclosure, but is not limited thereto.

Each of the memory blocks MB1 to MBk may be connected to local lines LL and bit lines BL1 to BLn, where n is a positive integer.

The local lines LL may be connected to a row decoder 122.

The local lines LL may be connected to each of the memory blocks MB1 to MBk.

Although not shown, the local lines LL may include a first select line, a second select line, and a plurality of word lines arranged between the first select line and the second select lines.

Although not shown, the local lines LL may further include dummy lines arranged between the first select line and the word lines, dummy lines arranged between the second select line and the word lines, and pipelines.

The bit lines BL1 to BLn may be commonly connected to the memory blocks MB1 to MBk.

The memory blocks MB1 to MBk may be implemented as a two-dimensional or three-dimensional structure.

For example, in the memory blocks MB1 to MBk of the two-dimensional structure, memory cells may be arranged in a direction parallel to a substrate.

For example, in the memory blocks MB1 to MBk of the three-dimensional structure, memory cells may be stacked on a substrate in a vertical direction.

The peripheral circuit 120 may include a voltage generator 121, the row decoder 122, a page buffer group 123, a column decoder 124, an input/output circuit 125, and a sensing circuit 126.

The voltage generator 121 may generate various operation voltages Vop used for the program operation, the read operation, and the erase operation in response to an operation command OP_CMD. In addition, the voltage generator 121 may selectively discharge the local lines LL in response to the operation command OP_CMD. For example, the voltage generator 121 may generate a program voltage, a verify voltage, pass voltages, a turn-on voltage, a read voltage, an erase voltage, a source line voltage, and the like under control of the control logic 130.

In an embodiment, the voltage generator 121 may regulate an external power voltage to generate an internal power voltage. The internal power voltage generated by the voltage generator 121 is used as an operation voltage of the memory device 100.

In an embodiment, the voltage generator 121 may generate a plurality of voltages using an external power voltage or an internal power voltage. For example, the voltage generator 121 may include a plurality of pumping capacitors that receive the internal power voltage, and may generate the plurality of voltages by selectively activating the plurality of pumping capacitors in response to the control of the control logic 130. The plurality of generated voltages may be supplied to the memory cell array 110 by the row decoder 122.

The row decoder 122 may transfer the operation voltages Vop to the local lines LL in response to a row address RADD. The operation voltages Vop may be transferred to selected memory blocks MB1 to MBk through the local lines LL.

For example, during the program operation, the row decoder 122 may apply the program voltage to a selected word line and a program pass voltage of a level different (e.g., less) than that of the program voltage to unselected word lines. During the program verify operation, the row decoder 122 may apply the verify voltage to the selected word line and a verify pass voltage different (e.g., greater) than the verify voltage to the unselected word lines.

During the read operation, the row decoder 122 may apply the read voltage to the selected word line, and apply a read pass voltage different (e.g., greater) than the read voltage to the unselected word lines.

During the erase operation, the row decoder 122 may select one memory block according to a decoded address. During the erase operation, the row decoder 122 may apply a reference (e.g., ground) voltage to word lines connected to the selected memory block.

The page buffer group 123 may include first to n-th page buffers PB1 to PBn. The first to n-th page buffers PB1 to PBn may be connected to the memory cell array 110 through the first to n-th bit lines BL1 to BLn, respectively. The first to n-th page buffers PB1 to PBn may operate in response to the control of the control logic 130.

Specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn, or may sense a voltage or a current of the bit lines BL1 to BLn during the read operation or the verify operation.

During the program operation, when the program voltage is applied to the selected word line, the first to n-th page buffers PB1 to PBn may transfer data DATA received through the column decoder 124 and the input/output circuit 125 to the selected memory cell through the first to n-th bit lines BL1 to BLn. The memory cells of the selected page are programmed according to the transferred data DATA. The memory cell connected to the bit line to which a program permission voltage (for example, a ground voltage) is applied may have an increased threshold voltage. The threshold voltage of the memory cell connected to the bit line to which a program inhibit voltage (for example, a power voltage) is applied may be maintained.

During the verify operation, the first to n-th page buffers PB1 to PBn may sense data stored in the memory cells selected through the first to n-th bit lines BL1 to BLn from the selected memory cells.

During the read operation, the first to n-th page buffers PB1 to PBn may sense the data DATA from the memory cells of the selected page through the first to n-th bit lines BL1 to BLn, and output the read data DATA to the input/output circuit 125 under the control of the column decoder 124.

During the erase operation, the first to n-th page buffers PB1 to PBn may float the first to n-th bit lines BL1 to BLn.

The column decoder 124 may transfer data between the input/output circuit 125 and the page buffer group 123 in response to a column address CADD. For example, the column decoder 124 may exchange data with the page buffers PB1 to PBn through data lines DL, or may exchange data with the input/output circuit 125 through column lines CL.

The input/output circuit 125 may transfer the command CMD and the address ADD received from the memory controller 200 to the control logic 130, or may exchange data DATA with the column decoder 124.

During the read operation or the verify operation, the sensing circuit 126 may generate a reference current in response to a permission bit signal VRY_BIT<#> and compare a sensing voltage VPB received from the page buffer group 123 with a reference voltage generated by the reference current to output a pass signal PASS or a fail signal FAIL.

The control logic 130 may output the operation command OP_CMD, the row address RADD, the page buffer control signals PBSIGNALS, and the permission bit VRY_BIT<#> in response to the command CMD and the address ADD to control the peripheral circuit 120.

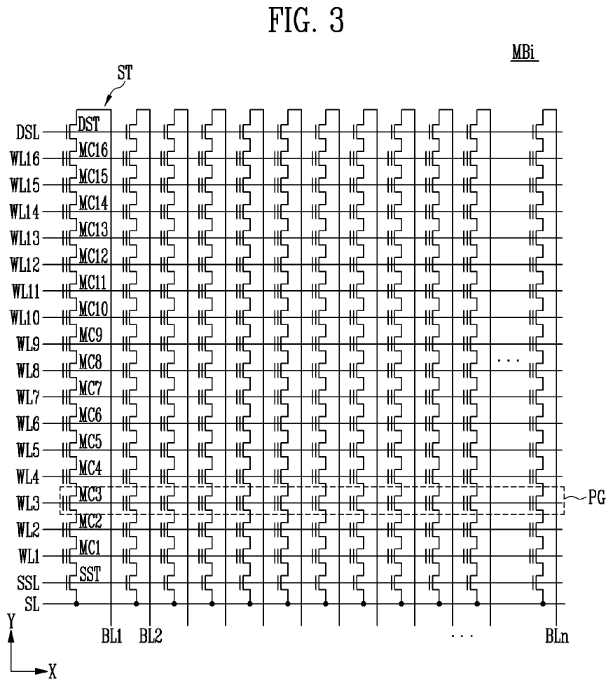

FIG. 3 is a diagram illustrating a memory block according to an embodiment of the present disclosure.

Referring to FIG. 3, the memory block MBi shown in FIG. 3 may be any of the memory blocks MB1 to MBk shown in FIG. 2.

The memory block MBi may include a first select line, a second select line, a plurality of word lines WL1 to WL16, a source line SL, a plurality of bit lines BL1 to BLn, and a plurality of strings ST.

The first select line may be, for example, a source select line SSL. Hereinafter, the first select line is the source select line SSL.

The second select line may be, for example, a drain select line DSL. Hereinafter, the second select line is the drain select line DSL.

The plurality of word lines WL1 to WL16 may be arranged in parallel between the source select line SSL and the drain select line DSL.

The number of word lines WL1 to WL16 shown in FIG. 3 is an example, and is not limited to that shown in the drawing.

The source line SL may be commonly connected to the plurality of strings ST.

The plurality of bit lines BL1 to BLn may be connected to the strings ST, respectively.

The plurality of strings ST may be connected to the bit lines BL1 to BLn and the source line SL.

Since the strings ST may be configured to be identical to each other, the string ST connected to the first bit line BL1 is specifically described as an example.

The string ST may include a plurality of memory cells MC1 to MC16, at least one first select transistor, and at least one second select transistor.

The plurality of memory cells MC1 to MC16 may be connected in series between a source select transistor SST and a drain select transistor DST.

Gate electrodes of the memory cells MC1 to MC16 may be connected to the plurality of word lines WL1 to WL16, respectively. Therefore, the number of memory cells MC1 to MC16 included in one string ST may be the same as the number of word lines WL1 to WL16.

Any of the plurality of memory cells MC1 to MC16 may be configured as any of an SLC that stores one bit of data, an MLC that stores two bits of data, a TLC that stores three bits of data, and a QLC that stores four bits of data. However, the present disclosure is not limited thereto, and the memory cell may store five or more bits of data.

A group of memory cells connected to the same word line among memory cells included in different strings ST may be a physical page PG. Therefore, the memory block MBi may include the physical pages PG corresponding to the number of word lines WL1 to WL16. Hereinafter, memory cells (for example, MC3) included in the physical page PG are selected memory cells.

The first select transistor may be, for example, a source select transistor SST. Hereinafter, the first select transistor is the source select transistor SST.

A first electrode of the source select transistor SST may be connected to the source line SL. A second electrode of the source select transistor SST may be connected to the first memory cell MC1 among the plurality of memory cells MC1 to MC16. A gate electrode of the source select transistor SST may be connected to the source select line SSL.

The second select transistor may be, for example, a drain select transistor DST. Hereinafter, the second select transistor is the drain select transistor DST.

A first electrode of the drain select transistor DST may be connected to the sixteenth memory cell MC16 among the plurality of memory cells MC1 to MC16. A second electrode of the drain select transistor DST may be connected to the first bit line BL1. A gate electrode of the drain select transistor DST may be connected to the drain select line DSL.

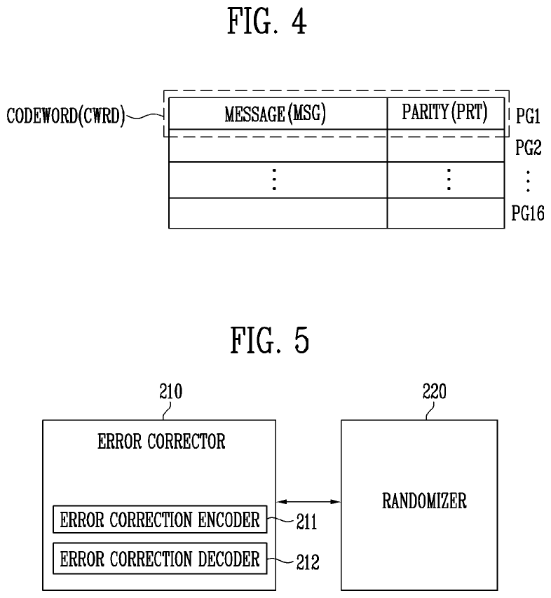

FIG. 4 is a diagram illustrating a codeword stored in a memory device according to an embodiment of the present disclosure.

Referring to FIG. 4, a plurality of pages PG1 to PG16 shown in FIG. 4 may be a plurality of pages included in the memory block MBi shown in FIG. 3. The number of pages shown in FIG. 4 may be 16, but is not limited thereto. Each page may be divided into a main area and a sub area.

In an embodiment, one codeword CWRD may be stored in one page. Alternatively, one codeword CWRD may be stored in one chunk. At this time, the chunk may represent a partial area of the page. Hereinafter, one codeword CWRD is stored in one page for convenience of description.

Referring to FIG. 4, the codeword CWRD may be stored in the first page PG1. The codeword CWRD may include a message MSG and a parity PRT. The message MSG may be stored in the main area of the first page PG1. The parity PRT may be stored in the sub area of the first page PG1.

The codeword CWRD may be configured of n bits. When the codeword CWRD is configured of the n bits, an inverted codeword obtained by inverting the codeword CWRD may also be configured of n bits.

The message MSG may be configured of k bits. When the message MSG is configured of k bits, an inverted message obtained by inverting the message MSG may also be configured of k bits.

FIG. 5 is a diagram illustrating an error corrector and a randomizer according to an embodiment of the present disclosure.

Referring to FIG. 5, the error corrector 210 may include an error correction encoder 211 and an error correction decoder 212.

In an embodiment, the error correction encoder 211 may perform error correction encoding on input data based on the generator matrix. At this time, the input data may include write data that is not inverted after being provided from the host 400, inverted write data that is inverted after being provided from the host 400, and the like.

For example, the error correction encoder 211 may receive the write data from the host 400. The error correction encoder 211 may perform the error correction encoding on the write data using the generator matrix of k rows and n columns. For example, the error correction encoder 211 may generate the codeword obtained by performing error correction encoding on the write data according to a systematic encoding method. The error correction encoder 211 may provide the codeword to the randomizer 220.

As another example, the error correction encoder 211 may receive the inverted write data output by the randomizer 220.

The error correction encoder 211 may encode the inverted write data using the generator matrix of k rows and n columns. For example, the error correction encoder 211 may perform the error correction encoding on the inverted write data according to a systematic encoding method.

The error correction decoder 212 may receive read data stored in the memory device 100. At this time, the read data may be the inverted codeword. The error correction decoder 212 may perform the error correction decoding on the read data using the parity check matrix of (n−k) rows and n columns. The error correction decoder 212 may restore a first message through the error correction decoding on the read data. At this time, the first message may refer to data on which the bit inversion operation is not performed after the error correction decoding is performed.

The error correction decoder 212 may provide the first message to the randomizer 220.

In an embodiment, the error corrector 210 may perform the error correction encoding or the error correction decoding using a binary low density parity check (LDPC) code. The parity check matrix based on the binary LDPC code may be a matrix in which the number of elements, each of which is 1, among elements included in each row is an even number.

In another embodiment, the error corrector 210 may perform the error correction encoding or the error correction decoding using a non-binary LDPC code. The parity check matrix based on the non-binary LDPC code may be a matrix in which an exclusive OR on elements included in each row is 0 (or 0 vector).

In an embodiment, the randomizer 220 may invert the input data. At this time, the data input to the randomizer 220 may include the write data provided from the host 400 or the codeword that is error correction encoded by the error correction encoder 211 after being provided from the host.

For example, the randomizer 220 may receive the codeword provided from the error correction encoder 211. The randomizer 220 may invert all bits of the codeword. For example, since bits of the codeword may have a value of 0 or 1, the bit having the value of 0 among the bits of the codeword may be inverted to a value of 1, and the bit having the value of 1 among the bits of the codeword may be inverted to a value of 0. The randomizer 220 may generate the inverted codeword obtained by inverting the codeword. At this time, the inverted codeword may refer to the inverted codeword. The inverted codeword may be provided to the memory device 100.

As another example, the randomizer 220 may receive the write data from the host 400. The randomizer 220 may invert all bit values of the write data. For example, the randomizer 220 may invert all values of each bit of the write data. The randomizer 220 may provide the inverted write data to the error correction encoder 211.

In addition, in an embodiment, the randomizer 220 may receive the first message from the error correction decoder. The randomizer 220 may invert all bits included in the first message. The randomizer 220 may generate a second message obtained by inverting the first message. The second message may be provided to the host 400.

FIG. 6 is a diagram illustrating an example of a parity check matrix according to an embodiment of the present disclosure.

Referring to FIG. 6, an example of a parity check matrix H defining an (n, k) code is shown. The (n, k) code may be defined as the parity check matrix H having a size of (n−k)×n.

Each element (or entry) of the parity check matrix H may be expressed as ‘0’ or ‘1’. When the number of ‘1’ included in the parity check matrix H is relatively small compared to the number of ‘0’, the (n, k) code may be referred to as (n, k) LDPC code. Here, n is a natural number, and k may be a natural number less than n. For example, a parity check matrix H defining (7, 4) code is shown in FIG. 6.

The parity check matrix H may include a matrix in which each element is formed in a sub matrix. This matrix may be defined as a base matrix. Each element of the base matrix may be a matrix having a size of m×m. Here, m may be an integer of 2 or more. In the base matrix, ‘0’ may indicate that a corresponding element is a zero matrix, and ‘1’ may indicate that the corresponding element is not a zero matrix. When the base matrix is used for a Quasi Cyclic (QC)-LDPC code, ‘1’ may indicate that the corresponding element is a circulant matrix. The circulant matrix may be a matrix obtained by cyclic shifting an identity matrix by a predetermined shift value, and one circulant matrix may have a shift value different from another circulant matrix.

The parity check matrix H according to an embodiment may be the matrix of the binary LDPC code, and the parity check matrix H of (n−k) rows and n columns may be the matrix in which the number of elements, each of which is 1 among n elements included in each row, is an even number. For example, in a case of the parity check matrix H of 3 rows and 7 columns or the parity check matrix H defining the (7, 4) code, the number of elements, each of which is 1 among seven elements included in 1 row may be four, the number of elements, each of which is 1 among the seven elements included in 2 row may be four, and the number of elements, each of which is 1 among the seven elements included in 3 row may be four. However, the present disclosure is not limited thereto.

FIG. 7 is a diagram illustrating a parity check matrix shown in FIG. 6 as a Tanner graph according to an embodiment of the present disclosure.

Referring to FIG. 7, the (n, k) code may be expressed as a Tanner graph corresponding to an equivalent bipartite graph. The Tanner graph may be expressed by (n−k) check nodes, n variable nodes, and edges. The check node corresponds to the row of the parity check matrix H, and the variable node corresponds to the column of the parity check matrix H. One edge connects one check node and one variable node, and represents an element expressed by 1 in the parity check matrix H.

In an embodiment, the parity check matrix H of (n−k) rows and n columns may include (n−k) check nodes and n variable nodes. Since each variable node corresponds to each row of the parity check matrix H and the number of 1s included in each row is an even number, n variable nodes may have an even order. For example, the parity check matrix of the (7, 4) code shown in FIG. 7 may be expressed as a Tanner graph including three check nodes CN₁ to CN₃ and seven variable nodes VN₁ to VN₇. A solid line connecting the check nodes CN₁ to CN₃ and the variable nodes VN₁. to VN₇ indicates the edge. Hereinafter, for convenience of description, the present embodiment is described based on the parity check matrix H defining the (7, 4) code.

An iterative decoding may be performed according to an iterative message transmission algorithm between the check nodes CN₁ to CN₃ and the variable nodes VN₁ to VN₇ on the Tanner graph. That is, the iterative decoding may be performed while a message is transmitted between the check nodes CN₁ to CN₃ and the variable nodes VN₁ to VN₇ for each iteration.

Each variable node may perform error correction using C2V messages received from check nodes connected thereto. Each variable node may generate V2C messages to be transmitted to check nodes connected thereto, and may transmit each of the generated V2C messages to a corresponding check node.

Each check node may perform a parity check using the V2C messages received from variable nodes connected thereto. A code bit included in the V2C message may be used for the parity check. Each check node may generate the C2V messages to be transmitted to the variable nodes connected thereto, and may transmit each of the generated C2V messages to a corresponding variable node.

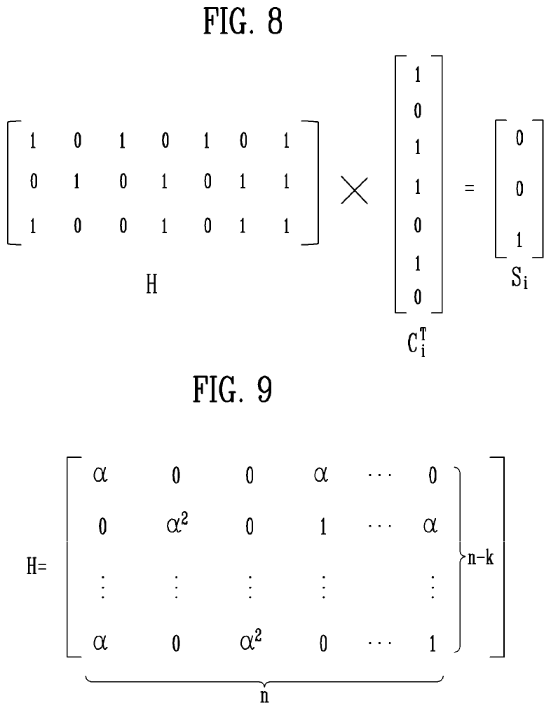

FIG. 8 is a diagram illustrating a syndrome vector calculated using the parity check matrix shown in FIG. 6 according to an embodiment of the present disclosure.

Referring to FIG. 8, a syndrome vector Sᵢ may be generated based on the parity check matrix H of (n−k) rows and n columns and a transpose matrix Cᵢ^{T} of a variable node vector Cᵢ corresponding to an i-th iteration.

Hereinafter, for convenience of description, the present embodiment is described based on the parity check matrix H defining the (7, 4) code shown in FIG. 6.

Symbols Sᵢ₁, Sᵢ₂, and Sᵢ₃ of the syndrome vector Sᵢ may correspond to the check nodes CN₁ to CN₃ on the Tanner graph shown in FIG. 7.

When at least one symbol among all symbols Sᵢ₁, Sᵢ₂, and Sᵢ₃ of the syndrome vector Sᵢ is not ‘0’, this means that a syndrome check is failed. This may mean that the error correction decoding is not successful in a corresponding iteration, and thus, when a maximum iteration number is not reached, a next iteration may be performed. Here, a symbol that is not ‘0’ may represent unsatisfied check nodes (UCN).

Referring to FIG. 8, for example, elements of the transpose matrix Cᵢ^{T} of the variable node vector Cᵢ corresponding to an i-th iteration are {1, 0, 1, 1, 0, 1, 0}. Since the elements included in 1 row of the parity check matrix H defining the (7, 4) code are {1, 0, 1, 0, 1, 0, 1}, according to a matrix multiplication operation between the elements included in the 1 row of the parity check matrix H and the elements of the transpose matrix Cᵢ^{T}, (1+0+1+0+0+0+0) is obtained. At this time, a (+) operation is an exclusive OR, a value of the first symbol Sᵢ₁ of the syndrome vector Sᵢ is 0. Similarly, according to a matrix multiplication operation between the elements included in each of the 2 row and the 3 row of the parity check matrix H and the elements of the transpose matrix Cᵢ^{T}, a value of the second symbol Sᵢ₂ of the syndrome vector Sᵢ is 0, and a value of the third symbol Sᵢ₃ is 1. That is, values of all symbols Sᵢ₁, Sᵢ₂, and Sᵢ₃ of the syndrome vector Sᵢ may be expressed as {0, 0, 1}. This case may mean that the syndrome check is failed.

When all symbols Sᵢ₁, Sᵢ₂, and Sᵢ₃ of the syndrome vector Sᵢ indicate ‘0’, this means that the syndrome check is passed. This means that the error correction decoding is successfully performed in the corresponding iteration. Therefore, iterative decoding for the corresponding codeword is ended, and the corresponding variable node vector Cᵢ may be output as a decoded codeword in the i-th iteration.

FIG. 9 is a diagram illustrating another example of a parity check matrix according to an embodiment of the present disclosure.

Referring to FIG. 9, the (n, k) code may be defined as the parity check matrix H having the size of (n−k)×n, as described above with reference to FIG. 6.

Each element of the parity check matrix H may be expressed as elements belonging to a Galois field. The Galois field GF(q) may be a finite field formed of q elements, and the elements of the Galois field GF(q) may be expressed as {0, a⁰, a¹, . . . , a^{q-2}}. When the number of non-zero elements a⁰, a¹, . . . , and a^{q-2} included in the parity check matrix H is relatively small compared to the number of 0, the (n, k) code may be defined as an (n, k) LDPC code.

The LDPC code belonging to the Galois field represented by GF(2) may mean the binary LDPC code. In the case of the parity check matrix H defining the code (7, 4) described above with reference to FIG. 6, the code (7, 4) may be the binary LDPC code belonging to the Galois field represented by GF(2).

The LDPC code belonging to the Galois field represented by GF(q) (here, q>2) may mean the non-binary LDPC code. The parity check matrix H shown in FIG. 9 having the size of (n−k)×n may be the matrix of the non-binary LDPC code having elements of GF(4) as entries.

The parity check matrix H according to another embodiment may be the matrix of the non-binary LDPC code, and the parity check matrix H of (n−k) rows and n columns may be the matrix in which the exclusive OR on the elements included in each row is 0. The exclusive OR may mean a logical operation in which an output value is 1 when the number of 1s among input elements is an odd number. For example, the exclusive OR between the elements a⁰, 0, 0, a⁰, . . . , and 0 included in the 1 row may be 0, the exclusive OR between the elements 0, a², 0, 1, . . . , and a⁰ included in the 2 row may be 0, and the exclusive OR between the elements a⁰, 0, a², 0, . . . , and 1 included in the (n−k) row may be 0. However, the present disclosure is not limited thereto.

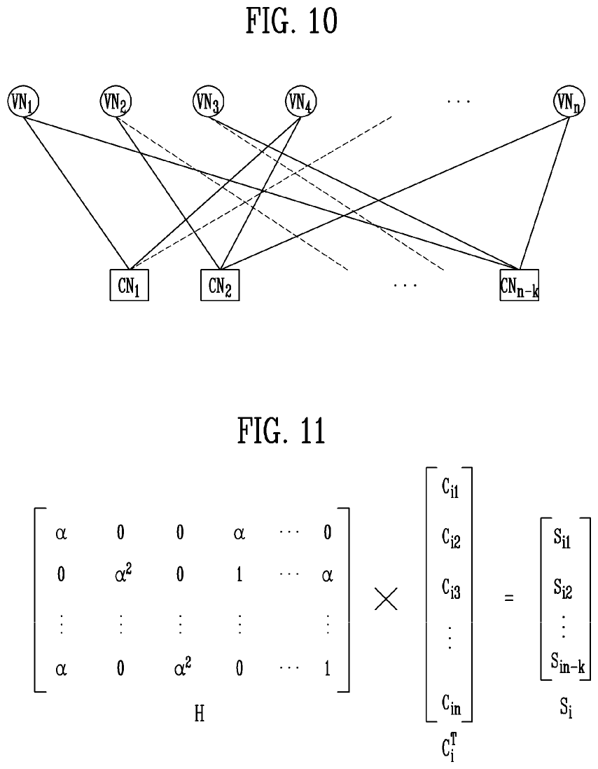

FIG. 10 is a diagram illustrating the parity check matrix shown in FIG. 9 as a Tanner graph according to an embodiment of the present disclosure.

Referring to FIG. 10, the Tanner graph may be configured of the check node, the variable node, and the edge, as described above with reference to FIG. 7. Each edge may connect one check node and one variable node, and may represent an entry expressed by an element that is not zero in the parity check matrix.

The parity check matrix of the (n, k) code may be expressed as a Tanner graph including (n−k) check nodes CN₁ to CNₙ₋ₖ and n variable nodes VN₁ to VNₙ. A solid line and a dotted line connecting the check nodes CN₁ to CNₙ₋ₖ and the variable nodes VN₁ to VNₙ represent the edge.

The iterative decoding may be performed according to the iterative message transmission algorithm between the check nodes CN₁ to CNₙ₋ₖ and the variable nodes VN₁ to VNₙ on the Tanner graph. That is, the iterative decoding may be performed while the C2V messages and the V2C messages are transmitted between the check nodes CN₁ to CNₙ₋ₖ and the variable nodes VN₁ to VNₙ for each iteration. The variable nodes may perform error correction using the C2V messages received from check nodes connected thereto, and the check nodes may check using the V2C messages received from the variable nodes connected thereto. In any check node, when a value obtained by performing an exclusive OR (XOR) operation on all variable nodes connected to any check node is formed of only 0, it may be determined that a corresponding check node is satisfied. On the other hand, in any check node, when the value obtained by performing an XOR operation on all variable nodes connected to any check node includes an element that is not 0, it may be determined that a corresponding check node is unsatisfied, and the corresponding check node may be referred to as the UCN. Here, the value of the variable nodes on which the XOR operation is performed may be a value on which an edge gain operation is performed.

FIG. 11 is a diagram illustrating a syndrome vector calculated using the parity check matrix shown in FIG. 9.

Referring to FIG. 11, the syndrome vector Sᵢ may be generated based on the parity check matrix H and the transpose matrix Cᵢ^{T} of the variable node vector Cᵢ that is a result value of the i-th iteration. Each of elements Sᵢ₁, Sᵢ₂, . . . , and Sᵢₙ₋ₖ of the syndrome vector Sᵢ corresponds to each of check nodes CN₁ to CNₙ₋ₖ on the Tanner graph shown in FIG. 10.

All elements Sᵢ₁, Sᵢ₂, . . . , and Sᵢₙ₋ₖ of the syndrome vector Sᵢ represent 0, this means that the syndrome check is passed. Therefore, the iterative decoding for the corresponding codeword is ended, and the variable node vector Cᵢ, which is a result value of the i-th iteration, may be output as a decoded codeword.

When at least one entry among all entries Sᵢ₁, Sᵢ₂, . . . , and Sᵢₙ₋ₖ of the syndrome vector Sᵢ is not 0, this means that the syndrome check is failed. Therefore, when a maximum iteration number is not reached, a next iteration may be performed. Here, the entry that is not 0 may represent the UCN.

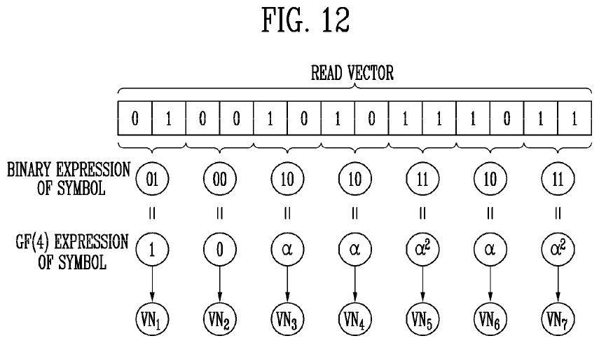

FIG. 12 is a diagram illustrating a symbol configuration process according to an embodiment of the present disclosure.

In the embodiment described with reference to FIG. 12, a vector of the codeword provided from the memory device 100 includes 14 bits.

The error correction decoder 212 may configure a plurality of symbols by grouping bits included in the vector of the codeword in a set number unit. For example, when GF(4) is used, the error correction decoder 212 may configure one symbol by grouping two bits. Since the vector of the codeword includes 14 bits, the error correction decoder 212 may configure a total of seven symbols. The error correction decoder 212 may sequentially allocate the total of seven symbols to the variable nodes VN1 to VN7.

A binary expression ‘00’ may correspond to a GF(4) expression ‘0’. A binary expression ‘01’ may correspond to a GF(4) expression ‘1’. A binary expression ‘10’ may correspond to a GF(4) expression ‘a’. A binary expression ‘11’ may correspond to a GF(4) expression ‘a2’.

FIG. 13 is a diagram illustrating a process of generating an inverted codeword according to a first policy according to an embodiment of the present disclosure.

In the embodiment described with reference to FIG. 13, the codeword is configured of seven bits, the message is configured of four bits, and a randomization method is a bit flip method. The message shown in FIG. 13 may represent the write data described with reference to FIG. 1.

Referring to FIG. 13, the error correction encoder 211 may receive the message MSG from the host 400. The message MSG configured of four bits is “0010”.

The error correction encoder 211 may generate the codeword CWRD by encoding the message MSG based on the generator matrix of k rows and n columns, and provide the codeword CWRD to the randomizer 220. The codeword CWRD may include the message MSG and the parity PRT, and the parity PRT included in the codeword CWRD configured of seven bits may be configured of 3 bits. The parity PRT configured of 3 bits is “110”.

The randomizer 220 may invert all bits of the codeword CWRD. The inverted codeword RCWRD obtained by inverting the codeword CWRD may be provided to the memory device 100. For example, when the message MSG included in the codeword CWRD is “0010”, a randomized message RMSG, that is, a bit flipped message may be “1101”. When the parity PRT included in the codeword CWRD is “110”, an inverted parity RPRT may be “001”.

FIG. 14 is a diagram illustrating a process of generating an inverted codeword according to a second policy according to an embodiment of the present disclosure.

In the embodiment described with reference to FIG. 14, the codeword is configured of seven bits, the message is configured of four bits, and the randomization method is a bit flip method. The message shown in FIG. 14 may represent the write data described with reference to FIG. 1.

Referring to FIG. 14, the randomizer 220 may receive the message MSG from the host 400. The message MSG configured of four bits is “0010”.

The randomizer 220 may invert all bits of the message MSG. An inverted message RMSG may be provided to the error correction encoder 211. At this time, the inverted message may represent the inverted write data described with reference to FIG. 1. For example, when the message MSG is “0010”, the inverted message RMSG, that is, a bit flipped message may be “1101”.

The error correction encoder 211 may receive the inverted message RMSG from the randomizer 220.

The error correction encoder 211 may generate the inverted codeword RCWRD by performing the error correction encoding on the inverted message RMSG. The inverted codeword RCWRD may be provided to the memory device 100. In this case, the inverted message RMSG included in the inverted codeword RCWRD may be “1101”. The inverted parity RPRT included in the inverted codeword RCWRD may be “001”.

As described above, since a bit inversion degree for the message and a bit inversion degree for the parity are identically maintained, there is an effect in which reliability of the read operation is improved.

FIG. 15 is a diagram illustrating a process of generating a message restored from read data according to an embodiment of the present disclosure.

Referring to FIG. 15, the error correction decoder 212 may receive the inverted codeword RCWRD from the memory device 100. At this time, the inverted codeword RCWRD may represent the inverted codeword RCWRD shown in FIG. 13 or 14. The error correction decoder 212 may perform the error correction decoding on the inverted codeword RCWRD using the parity check matrix H of (n−k) rows and n columns.

For example, when the error correction decoder 212 uses the binary LDPC code, the parity check matrix H of (n−k) rows and n columns may be the matrix in which the number of elements, each of which is 1 among n elements included in each row is an even number, as described above with reference to FIG. 6.

For another example, when the error correction decoder 212 uses the non-binary LDPC code, the parity check matrix H of (n−k) rows and n columns may be the matrix in which the exclusive OR on the elements included in each row is 0, as described above with reference to FIG. 9.

When the error correction decoding on the inverted codeword RCWRD is completed, the error correction decoder 212 may provide the inverted message RMSG to the randomizer 220. At this time, the inverted message RMSG may represent the first message described with reference to FIG. 1.

The randomizer 220 may generate the message MSG by inverting all bits of the inverted message RMSG. At this time, the message MSG may represent the second message described with reference to FIG. 1. The message MSG may be provided to the host 400.

According to that described above, there is an effect in which the reliability of the read operation is improved through homogeneous inversion of a pattern. Specifically, according to an embodiment of the present disclosure, by first performing the error correction decoding before performing the bit inversion operation, the reliability of the read operation may be improved and an error correction decoding operation may be simplified. In particular, in a case of a soft decoding operation, soft read data read from the memory device 100 may be used as input data of the error correction decoder 212. Accordingly, a process of converting the soft read data into log likelihood ratio (LLR) data may be simplified, thereby simplifying the soft decoding operation.

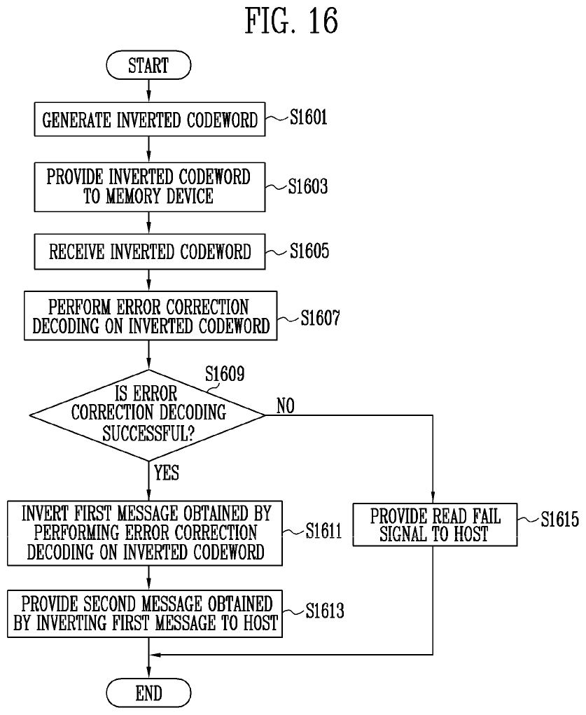

FIG. 16 is a flowchart illustrating a method of operating a memory controller according to an embodiment of the present disclosure.

The method shown in FIG. 16 may be performed, for example, by the memory controller 200 shown in FIG. 1.

Referring to FIG. 16, in operation S1601, the memory controller 200 may generate the inverted codeword in response to the write request of the host 400. For example, the memory controller 200 may generate the inverted codeword according to a preset one of the first policy and the second policy based on the write data to be stored in the memory device 100 and the generator matrix.

In operation S1603, the memory controller 200 may provide the inverted codeword to the memory device 100.

In operation S1605, the memory controller 200 may receive the inverted codeword from the memory device 100 in response to the read request of the host 400.

In operation S1607, the memory controller 200 may perform the error correction decoding on the inverted codeword based on the parity check matrix. At this time, the parity check matrix may be the matrix in which the number of elements, each of which is 1 among the elements included in each row, is an even number, or the matrix in which the exclusive OR on the elements included in each row is 0.

In operation S1609, the memory controller 200 may determine whether the error correction decoding on the inverted codeword is successful. When it is determined that the error correction decoding is successful, the memory controller 200 may perform operation S1611.

In operation S1611, the memory controller 200 may invert the first message obtained by performing the error correction decoding on the inverted codeword.

In operation S1613, the memory controller 200 may provide the second message obtained by inverting the first message to the host 400.

Further, when it is determined that the error correction decoding is failed in operation S1609, the memory controller 200 may perform operation S1615.

In operation S1615, the memory controller 200 may provide a read fail signal to the host 400.

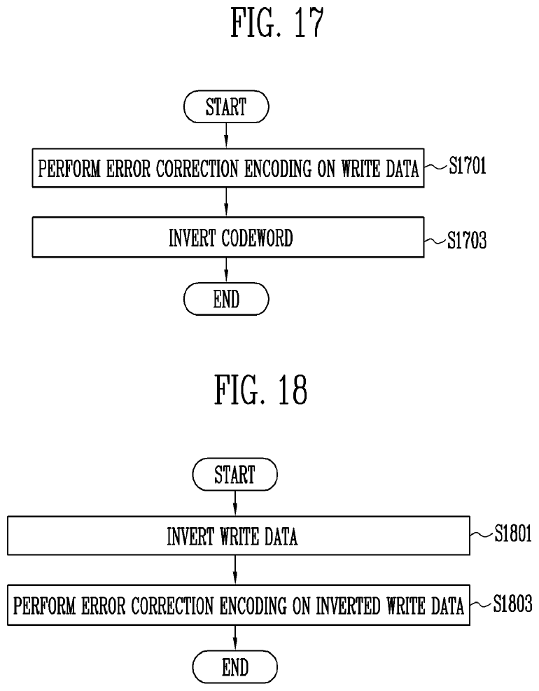

FIG. 17 is a flowchart illustrating a method of generating an inverted codeword according to a first policy according to an embodiment of the present disclosure.

The method shown in FIG. 17 may be performed, for example, by the memory controller 200 shown in FIG. 1. The method shown in FIG. 17 may be a method that embodies operation S1601 shown in FIG. 16.

Referring to FIG. 17, in operation S1701, the memory controller 200 may perform the error correction encoding on the write data according to the first policy.

In operation S1703, the memory controller 200 may invert the codeword obtained by performing the error correction encoding on the write data. At this time, the inverted codeword may be data obtained by inverting the codeword on which the error correction encoding is performed.

FIG. 18 is a flowchart illustrating a method of generating an inverted codeword according to a second policy according to an embodiment of the present disclosure.

The method shown in FIG. 18 may be performed, for example, by the memory controller 200 shown in FIG. 1. The method shown in FIG. 18 may be a method that embodies operation S1601 shown in FIG. 16.

Referring to FIG. 18, in operation S1801, the memory controller 200 may invert the write data according to the second policy.

In operation S1803, the memory controller 200 may perform the error correction encoding on the inverted write data obtained by inverting the write data. At this time, the inverted codeword may be data obtained by performing the error correction encoding on the inverted write data.

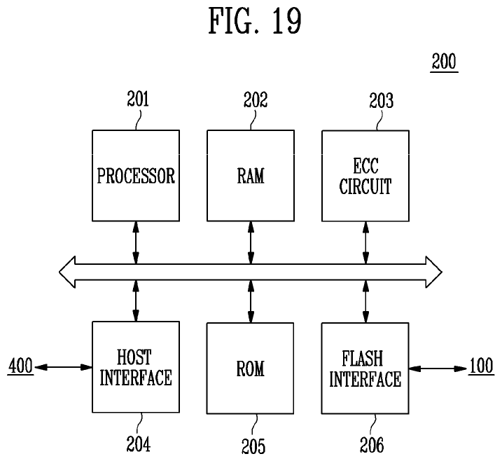

FIG. 19 is a diagram illustrating the memory controller of FIG. 1 according to an embodiment of the present disclosure.

Referring to FIG. 19, the memory controller 200 may include a processor 201, a RAM 202, an error correction circuit 203, a host interface 204, a ROM 205, and a flash interface 206.

The processor 201 may control an overall operation of the memory controller 200.

The RAM 202 may be used as a buffer memory, a cache memory, an operation memory, and the like of the memory controller 200. For example, the RAM 202 may be a buffer memory.

The error correction circuit 203 may generate an error correction code (ECC) for correcting a fail bit or an error bit of data received from the memory device 100.

The error correction circuit 203 may perform error correction encoding of data provided to the memory device 100 to generate data to which a parity bit is added. The parity bit (not shown) may be stored in the memory device 100.

The error correction circuit 203 may perform error correction decoding on the data output from the memory device 100, and at this time, the error correction circuit 203 may correct an error using parity.

For example, the error correction circuit 203 may correct the error using various coded modulations such as an LDPC code, a BCH code, a turbo code, a Reed-Solomon code, a convolution code, an RSC, a TCM, and a BCM.

The error correction circuit 203 may calculate an error correction code value of data to be programmed to the memory device 100 in the program operation.

The error correction circuit 203 may perform an error correction operation based on the error correction code value on data read from the memory device 100 in the read operation.

The error correction circuit 203 may perform an error correction operation of data recovered from the memory device 100 in a recovery operation of failed data.

In an embodiment, the error correction circuit 203 may include the error corrector 210 and the randomizer 220 shown in FIG. 1.

The memory controller 200 may communicate with an external device (for example, the host 400, an application processor, and the like) through the host interface 204.

The ROM 205 may store various pieces of information required to operate the memory controller 200 in a firmware form.

The memory controller 200 may communicate with the memory device 100 through the flash interface 206. The memory controller 200 may transmit the command CMD, the address ADDR, a control signal CTRL, and the like to the memory device 100 and receive data through the flash interface 206.

For example, the flash interface 206 may include a NAND interface.

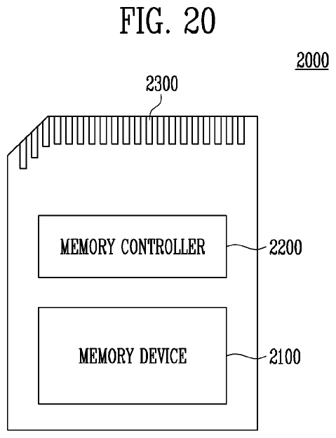

FIG. 20 is a block diagram illustrating a memory card system to which a storage device according to an embodiment of the present disclosure is applied.

Referring to FIG. 20, the memory card system 2000 includes a memory device 2100, a memory controller 2200, and a connector 2300.

For example, the memory device 2100 may be configured of various nonvolatile memory elements such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-transfer torque magnetoresistive RAM (STT-MRAM).

The memory controller 2200 is connected to the memory device 2100. The memory controller 2200 is configured to access the memory device 2100. For example, the memory controller 2200 may be configured to control read, write, erase, and background operations of the memory device 2100. The memory controller 2200 is configured to provide an interface between the memory device 2100 and the host 400. The memory controller 2200 is configured to drive firmware for controlling the memory device 2100. The memory controller 2200 may be implemented identically to the memory controller 200 described with reference to FIG. 1.

For example, the memory controller 2200 may include components such as a random access memory (RAM), a processor, a host interface, a memory interface, and an error correction circuit.

The memory controller 2200 may communicate with an external device through the connector 2300. The memory controller 2200 may communicate with an external device (for example, the host 400) according to a specific communication standard. For example, the memory controller 2200 is configured to communicate with an external device through at least one of various communication standards or interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 2300 may be defined by at least one of the various communication standards or interfaces described above.

The memory device 2100 and the memory controller 2200 may be integrated into one semiconductor device to configure a memory card. For example, the memory controller 2200 and the memory device 2100 may be integrated into one semiconductor device to configure a memory card such as a PC card (personal computer memory card international association (PCMCIA)), a compact flash card, a smart media card (SM or SMC), a memory stick, a multimedia card (MMC, RS-MMC, MMCmicro, or eMMC), an SD card (SD, miniSD, microSD, or SDHC), and a universal flash storage (UFS).

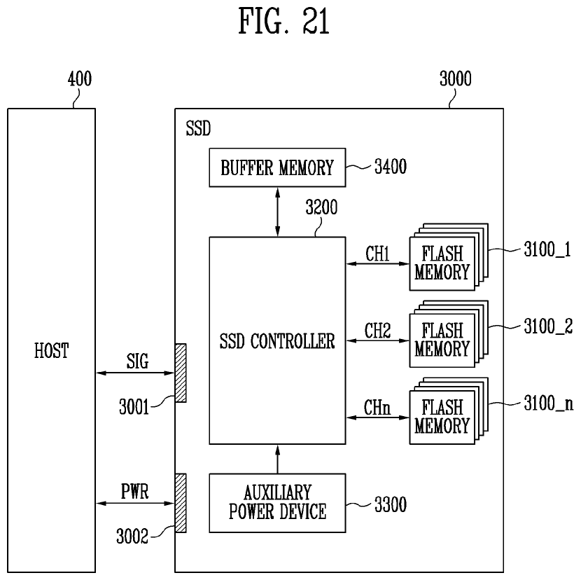

FIG. 21 is a block diagram illustrating a solid state drive (SSD) system to which a storage device according to an embodiment of the present disclosure is applied.

Referring to FIG. 21, the SSD system includes the host 400 and an SSD 3000.

The SSD 3000 exchanges a signal SIG with the host 400 through a signal connector 3001 and receives power PWR through a power connector 3002. The SSD 3000 includes an SSD controller 3200, a plurality of flash memories 3100_1, 3100_2, and 3100_n, an auxiliary power device 3300, and a buffer memory 3400.

According to an embodiment of the present disclosure, the SSD controller 3200 may perform the function of the memory controller 200 described with reference to FIG. 1.

The SSD controller 3200 may control the plurality of flash memories 3100_1, 3100_2, and 3100_n in response to the signal SIG received from the host 400. For example, the signal SIG may be signals based on an interface between the host 400 and the SSD 3000. For example, the signal SIG may be a signal defined by at least one of communication standards or interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power device 3300 is connected to the host 400 through the power connector 3002. The auxiliary power device 3300 may receive the power PWR from the host 400 and may charge the power. The auxiliary power device 3300 may provide power to the SSD 3000 when power supply from the host 400 is not smooth. For example, the auxiliary power device 3300 may be positioned in the SSD 3000 or may be positioned outside the SSD 3000. For example, the auxiliary power device 3300 may be positioned on a main board and may provide auxiliary power to the SSD 3000.

The buffer memory 3400 may temporarily store data. For example, the buffer memory 3400 may temporarily store data received from the host 400 or data received from the plurality of flash memories 3100_1, 3100_2, and 3100_n, or may temporarily store meta data (for example, a mapping table) of the flash memories 3100_1, 3100_2, and 3100_n. The buffer memory 3400 may include a volatile memory such as a DRAM, an SDRAM, a DDR SDRAM, an LPDDR SDRAM, and a GRAM, or a nonvolatile memory such as an FRAM, a ReRAM, an STT-MRAM, and a PRAM.

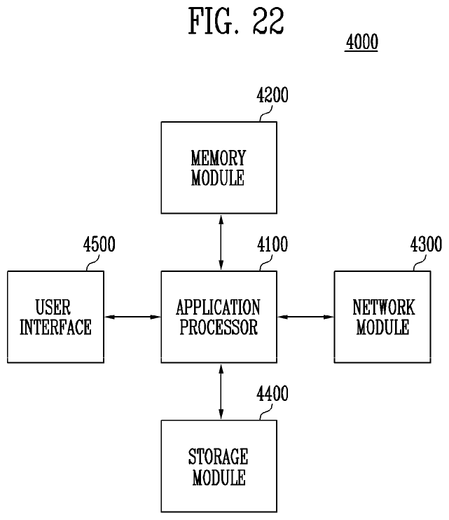

FIG. 22 is a block diagram illustrating a user system to which a storage device according to an embodiment of the present disclosure is applied.

Referring to FIG. 22, the user system 4000 includes an application processor 4100, a memory module 4200, a network module 4300, a storage module 4400, and a user interface 4500.

The application processor 4100 may drive components, an operating system (OS), a user program, or the like included in the user system 4000. For example, the application processor 4100 may include controllers, interfaces, graphics engines, and the like that control the components included in the user system 4000. The application processor 4100 may be provided as a system-on-chip (SoC).

The memory module 4200 may operate as a main memory, an operation memory, a buffer memory, or a cache memory of the user system 4000. The memory module 4200 may include a volatile random access memory such as a DRAM, an SDRAM, a DDR SDRAM, a DDR2 SDRAM, a DDR3 SDRAM, an LPDDR SDARM, an LPDDR2 SDRAM, and an LPDDR3 SDRAM, or a nonvolatile random access memory, such as a PRAM, a ReRAM, an MRAM, and an FRAM. For example, the application processor 4100 and memory module 4200 may be packaged based on a package on package (POP) and provided as one semiconductor package.

The network module 4300 may communicate with external devices. For example, the network module 4300 may support wireless communication such as code division multiple access (CDMA), global system for mobile communications (GSM), wideband CDMA (WCDMA), CDMA-2000, time division multiple access (TDMA), long term evolution, Wimax, WLAN, UWB, Bluetooth, and Wi-Fi. For example, the network module 4300 may be included in the application processor 4100.

The storage module 4400 may store data. For example, the storage module 4400 may store data received from the application processor 4100. Alternatively, the storage module 4400 may transmit data stored in the storage module 4400 to the application processor 4100. For example, the storage module 4400 may be implemented with a nonvolatile semiconductor memory element such as a phase-change RAM (PRAM), a magnetic RAM (MRAM), a resistive RAM (RRAM), a NAND flash, a NOR flash, and a three-dimensional NAND flash. For example, the storage module 4400 may be provided as a removable storage device (removable drive), such as a memory card, and an external drive of the user system 4000.

For example, the storage module 4400 may operate identically to the storage device 1000 described with reference to FIG. 1. The storage module 4400 may include a plurality of nonvolatile memory devices, and the plurality of nonvolatile memory devices may operate identically to the memory device 100 described with reference to FIG. 1.

The user interface 4500 may include interfaces for inputting data or an instruction to the application processor 4100 or for outputting data to an external device. For example, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may include user output interfaces such as a liquid crystal display (LCD), an organic light emitting diode (OLED) display device, an active matrix OLED (AMOLED) display device, an LED, a speaker, and a monitor.

Furthermore, the embodiments of the present disclosure have been described in the drawings and specification. Although specific terminologies are used here, those are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein and the following claims. The embodiments may be combined to form additional embodiments.

What is claimed is:

1. A memory controller comprising:
an error corrector configured to receive read data from a memory device and output a first message obtained by performing error correction decoding on the read data based on a parity check matrix;
a randomizer configured to generate a second message by inverting the first message; and
an operation controller configured to output the second message,
wherein the parity check matrix is a matrix in which a number of elements, each of which is one (1) among elements included in each row, is an even number or a matrix in which an exclusive OR on elements included in each row is zero (0).

2. The memory controller of claim 1, wherein the read data is a codeword obtained by performing error correction encoding on write data provided from a host by the error corrector, and then inverting by the randomizer.

3. The memory controller of claim 1, wherein the read data is a codeword obtained by inverting write data provided from a host by the randomizer, and then performing error correction encoding by the error corrector.

4. The memory controller of claim 1, wherein the parity check matrix is the matrix in which the number of elements, each of which is one (1) among the elements included in each row, is the even number when the error correction decoding of the read data is performed based on a binary low density parity check (LDPC) code.

5. The memory controller of claim 1, wherein the parity check matrix is the matrix in which the exclusive OR on the elements included in each row is zero (0) when the error correction decoding of the read data is performed based on a non-binary LDPC code.

6. The memory controller of claim 1, wherein the randomizer generates the second message by inverting all bits included in the first message.

7. A method of operating a memory controller, the method comprising:
generating an inverted codeword according to a preset one of a first policy and a second policy based on write data to be stored in a memory device and a generator matrix, in response to a write request of a host;
providing the inverted codeword to the memory device;
receiving the inverted codeword from the memory device in response to a read request of the host;
performing error correction decoding on the inverted codeword based on a parity check matrix to generate a first message;
inverting the first message to generate a second message; and
providing the second message to the host,
wherein the parity check matrix is a matrix in which a number of elements, each of which is one (1) among elements included in each row, is an even number or a matrix in which an exclusive OR on elements included in each row is zero (0).

8. The method of claim 7, wherein the generating of the inverted codeword comprises:
performing error correction encoding on the write data according to the first policy to generate a codeword; and
inverting the codeword to generate the inverted codeword.

9. The method of claim 7, wherein the generating of the inverted codeword comprises:
inverting the write data according to the second policy to generate inverted write data; and
performing error correction encoding on the inverted write data to generate the inverted codeword.

10. The method of claim 7, wherein the inverting of the first message comprises inverting all bits included in the first message.

11. The method of claim 7,
wherein the parity check matrix is the matrix in which the number of elements, each of which is one (1) among the elements included in each row, is the even number when the error correction decoding is performed based on a binary low density parity check (LDPC) code, and
wherein the parity check matrix is the matrix in which the exclusive OR on the elements included in each row is zero (0) when the error correction decoding is performed based on a non-binary LDPC code.

12. The method of claim 7, further comprising determining whether the error correction decoding is successful after the performing of the error correction decoding.

13. The method of claim 12, wherein the first message is inverted when the error correction decoding is successful.

14. The method of claim 12, further comprising providing a read fail signal to the host in response to failure of the error correction decoding.

15. An operating method of a controller, the operating method comprising:
error-correction-decoding on a codeword, which is read out from a memory device, based on a parity check matrix to generate a message; and
bitwise-inverting the message to provide a host with the bitwise-inverted message,
wherein the parity check matrix includes one or more rows each having even number of ones (1s) or one or more rows, each having elements, on which exclusive OR results in zero (0), and
wherein the generator matrix and the parity check matrix have a relationship as follows:
GH^{T}=0, where ‘G’ represents the generator matrix and ‘HT’ represents a transpose matrix of the parity check matrix.

16. The operating method of claim 15, wherein the codeword is data that is error-correction-encoded based on a generator matrix and then bitwise-inverted when stored into the memory device.

17. The operating method of claim 15, wherein the codeword is data that is bitwise-inverted and then error-correction-encoded based on a generator matrix when stored into the memory device.
